(19) United States
(12) Patent Application Publication
(10) Pub. No.: US 2026/0210442 A1
(43) Pub. Date: Jul. 23, 2026

(54) PNEUMATIC GAS INLET VALVE WITH ADJUSTABLE STOP

(71) Applicant: VAT HOLDING AG, Haag (CH)

(72) Inventors: Florian EHRNE, Frümsen (CH); Christof BACHMANN, Sennwald (CH); Raphael HARDEGGER, Sennwald (CH)

(21) Appl. No.: 19/114,327

(22) PCT Filed: Sep. 22, 2023
(86) PCT No.: PCT/EP2023/076188

§ 371 Date: Mar. 21, 2025

(30) Foreign Application Priority Data
Sep. 23, 2022 (DE) 10 2022 003 518.9

(51) Int. Cl. F16K 1/52; F16K 31/124; F16K 37/00; H10P 72/00

(52) U.S. Cl. CPC F16K 1/523; F16K 31/124; F16K 37/0083; H10P 72/0402

(57) ABSTRACT

Aspects include a gas inlet valve. The gas inlet valve includes: a gas passage unit, where the gas passage unit has a sealing surface in an inner volume, an adjustment device having an adjustment unit, where the adjustment unit projects into the inner volume, and a flexible sealing element which seals the adjustment device from the inner volume. The adjustment device has a pretensioning element to provide a pretensioning force pressing the valve disk in the closing direction. The adjustment device has a pneumatic drive cylinder coupled to the adjustment unit and an opening force counteracting the pretensioning force. The adjustment device has a limiting element. The limiting element is shaped and mounted in such a way that a position of the stop point along the adjustment axis can be varied by actuating the limiting element, wherein the position of the stop point defines a maximum valve opening.

### FIELD OF INVENTION

The present invention relates to a gas inlet valve for admitting a fluid into a vacuum process chamber.

### BACKGROUND OF THE INVENTION

Such vacuum process chambers are used for integrated circuit (IC), semiconductor, flat panel or substrate manufacturing, wherein the vacuum chambers are flooded with a process gas after evacuation for at least part of the process steps. The manufacturing process must take place in a protected atmosphere and, if possible, without the presence of contaminating particles. Evacuation takes place using a vacuum valve, which connects the vacuum process chamber to a vacuum pump and differs from a gas inlet valve in its design and technical requirements.

Furthermore, such vacuum chambers have at least one or two vacuum chamber openings through which the elements to be processed can be guided into and/or out of the vacuum chamber. For example, in a production system for semiconductor wafers or liquid crystal substrates, the highly sensitive semiconductor or liquid crystal elements pass sequentially through several vacuum process chambers in which the elements are processed by means of a processing device in each case.

For example, the element can be placed on extended support pins of a lifting system by means of a robot and deposited on a support, e.g. a potential plate (chuck), by lowering the support pins. After that, the robot arm, which typically carries the element, is moved out of the chamber. The pins can be lowered after the element has been deposited and are then separate from the element, i.e. there is no contact between the pins and the element. After removing the robot arm and closing the chamber, the chamber is usually evacuated and then filled with a process gas, whereupon processing of the element can start.

Gas inlet valves are designed in particular for defined control or regulation of the gas flow and are located, for example, within a pipe system between a vacuum process chamber (or a transfer chamber) and a gas source, the atmosphere or another vacuum process chamber. The opening cross-section such gas inlet valves is usually smaller than that of a vacuum valve.

Depending on the application, gas inlet valves can be used not only to fully open and close an opening, but also to control or regulate a flow by continuously adjusting the opening cross-section between an open position and a gas-tight closed position.

When admitting the process gas into the vacuum chamber, low fluidic effects within the chamber as well as fast and precise filling of the chamber are of great importance. For example, a defined quantity or volume of a defined process gas is to be admitted into the chamber with one opening cycle of the gas inlet valve. For this purpose, on the one hand, a fast actuation of the valve as well as a precise adjustment of the valve opening cross-section provided in the process is desirable.

### OBJECT OF THE INVENTION

Therefore, it is an object of the invention to provide an improved gas inlet valve for a vacuum process chamber.

In particular, the object is to provide a fast and at the same time continuously precise flooding of a vacuum process chamber with a process gas using the gas inlet valve.

Another object of the invention relates to providing a defined opening cross-section over a large period of time.

A further object is in particular the provision of a gas inlet valve which provides a defined flow factor for a specific process fluid.

### SUMMARY OF THE INVENTION

The present invention relates to a gas inlet valve having a pneumatic drive for the controlled opening of the valve. The gas inlet valve has a restoring element, in particular a spring, which presses the valve disk of the valve onto the valve seat and thus interrupts a flow path for a fluid through the valve. By means of the pneumatic drive, a force can be effected against the restoring force caused by the restoring element and the valve can thus be opened.

In the context of the present invention, fluid is understood to be at least a gas, a gas mixture, a liquid, a precursor-containing gas or a gas-liquid mixture. In particular, the fluid may be a process gas or precursor gas.

The valve disk and/or the valve seat (sealing surface) can have a sealing ring which is compressed in the closed position. The compression is caused by the pretensioning of the restoring element and ensures that the gas inlet can be separated from the gas outlet in a gas-tight manner.

A stop is provided to define the valve stroke, i.e. a distance over which the valve disk is adjusted during the opening process. This means that simply by providing pneumatic pressure in the drive, on the one hand a comparatively fast (compared, for example, to a mechatronic drive with an electric motor) opening movement of the valve disk can be implemented and, on the other hand, the opening movement can be limited accordingly. This means that a defined flow rate can be provided per unit of time simply by pressurizing the pneumatic drive.

By means of a control of the duration of pressurization, a quantity of fluid flowing through the valve, e.g. into a vacuum chamber, can further be adjusted for a valve opening cycle.

The stop of the gas inlet valve is further configured such that a stop point limits the adjustability of the valve disk along a linear adjustment axis in an opening direction, and a position of the stop point is movable along this adjustment axis by means of an actuation of the stop.

The stop point thus defines the maximum valve opening, in particular a stroke of the valve disk, i.e. a distance between the valve disk and the valve seat, when the pneumatic drive is pressurized. The valve stroke can thus be adjusted accordingly by moving the stop point.

The present invention thus relates to a gas inlet valve for the controlled inlet or flow of a fluid into a vacuum process chamber, with the gas inlet valve comprising a gas passage unit having a gas inlet, a gas outlet, and an inner volume. The inner volume connects the gas inlet and the gas outlet. The gas passage unit also has a sealing surface in the inner volume.

The gas inlet valve further has an adjustment device having an adjustment unit, wherein the adjustment unit projects into the inner volume and is mounted outside the gas passage unit in the adjustment device so as to be adjustable along an adjustment axis, wherein the adjustment unit has a valve disk which is arranged inside the inner volume. The valve disk can be brought by means of the adjustment device in the closing direction into a closed position in which the valve disk rests on the sealing surface and thus prevents gas from passing through, and the valve disk can be brought by means of the adjustment device in the opening direction into an open position in which the valve disk is spaced apart from the sealing surface and gas can pass through.

The adjustment device also has a pneumatic drive cylinder having at least one piston, wherein the piston is coupled to the adjustment unit and at least one opening force can be generated in the opening direction by pressurizing the drive cylinder or the piston, In particular, the pneumatic drive cylinder can be designed in such a way that a closing force can also be generated in the closing direction by means of a modified pressurization (e.g. on the opposite side of the piston). A respective pressurization can be effected, for example, by means of at least one compressed air outlet which projects into the drive cylinder or is embodied therein. The compressed air outlet is connected in particular to a pneumatic unit or a pneumatic valve.

The valve also has a flexible sealing element that is attached to the gas passage unit and to the adjustment unit and separates or seals the adjustment unit from the inner volume. The sealing element is designed in particular as a metal-containing membrane.

According to the invention, the adjustment device has a limiting element, which limiting element provides a stop point that limits adjustability of the adjustment unit along the adjustment axis in the opening direction. The limiting element is shaped and mounted in such a way that a position of the stop point along the adjustment axis can be varied by actuating the limiting element, with the position of the stop point defining a maximum valve opening.

The position of the stop point thus also defines the open position of the valve in particular.

The actuation of the limiting element thus causes an adjustment of the stop point along the adjustment axis. This adjustment option is particularly advantageous since the valve and its (mechanical and movable) components may have tolerances with regard to their dimensions and/or bearings due to the manufacturing process and thus different valve strokes (and maximum valve opening cross sections) may exist for (identically) manufactured valves, for example, The valve stroke corresponds in particular to the distance covered by the valve disk when it is adjusted from the maximum open position to the closed position (or vice versa). The possibility of adjusting the stop point thus provides a calibration, i.e. an adjustment of the valve stroke or of a maximum valve opening, for the gas inlet valve, so that each manufactured valve has the same flow characteristics after such a calibration, in particular the same valve stroke.

In particular, calibration of the valve can be carried out in an automated manner. For this purpose, a flow rate through the valve can be measured, preferably in the open position, and the flow rate through the valve can be adjusted to a set value by setting or adjusting the position of the stop point. Alternatively, the dynamic pressure upstream of the valve can be measured to determine the flow factor (Cᵥ). The pressure loss of the valve can also be measured.

In one embodiment, the adjustment device can have a pretensioning element arranged and interacting with the adjustment unit in such a way, in particular one or more springs or elastic elements, that a pretensioning force pressing the valve disk in the closing direction is provided. In particular, the pretensioning element is appropriately pretensioned in the open position of the valve.

Pressurizing the drive cylinder can generate an opening force in the opening direction that counteracts the pretensioning force. In particular, the pretensioning element can be in active contact with the at least one piston.

The gas inlet valve according to the invention combines the advantage of a comparatively fast opening of the valve by means of the pneumatic drive cylinder with a high precision and flexible adjustability with regard to the valve opening that can be provided with it, for example depending on a fluid flowing through.

In one embodiment, the gas inlet valve may include a controllable drive and the drive may be connected or coupled to the limiting element such that the position of the stop point can be varied by means of the drive.

In particular, the drive can be designed as an electric motor, in particular a servomotor or stepper motor, as a piezo element or as an actuator based on the magnetic bearing principle (e.g. PM linear magnet).

The connection of the limiting element to the drive enables in particular the controlled and/or automatic actuation of the limiting element and thus the corresponding controlled and/or automatic adjustment of the position of the stop point.

In one embodiment, the gas inlet valve may include a control and processing unit arranged at least to control the drive.

In one embodiment, the control and processing unit may have an adjustment functionality for adjusting the position of the stop point, wherein the adjustment functionality is configured such that, when executed, the following steps are carried out: Processing reference information (e.g. set pressure, set temperature, set flow rate, etc.), processing actual information (e.g. actual pressure, actual temperature, actual flow rate, density and/or composition of the fluid, etc.), comparing the reference information with the actual information, deriving adjustment information based on the comparison, and adjusting the position of the stop point based on the adjustment information, in particular automatic adjustment.

The automatic adjustment of the position of the stop point can, for example, be carried out by means of a closed-loop control. Here, the adjustment functionality can be executed continuously and the position of the stop point is changed until no further actuation of the limiting element appears necessary based on the adjustment information from the comparison of the reference information with the actual information.

According to one embodiment, the actual information can have information about a fluid property, in particular about a composition, type or nature of the fluid, and the reference information can provide an assignment of fluid properties to respective positions of the stop point. This allows, for example, automatic adjustment of the open position as a function of a fluid used, and a desired flow rate for a respective fluid can be provided in an automatically controlled manner. The information about a fluid condition can be provided by a user, for example.

In one embodiment, the reference information may have information about a set pressure of the fluid and the actual information may provide a current fluid pressure, in particular wherein the gas inlet valve has a pressure sensor for determining the fluid pressure.

According to one embodiment, the reference information may have information about a set temperature of the fluid and the actual information may provide a current fluid temperature, in particular wherein the gas inlet valve has a temperature sensor for determining the fluid temperature.

In one embodiment, the reference information may have information about a set flow factor for the fluid and the actual information may provide a current fluid flow factor, in particular wherein the gas inlet valve has a flow measurement unit for determining the fluid flow factor.

According to one embodiment, the reference information can have information about a set flow factor and the actual information can specify or provide a density and/or temperature of the fluid or a differential pressure, in particular wherein by means of the density and/or temperature of the fluid and/or by means of the differential pressure a fluid flow factor for the fluid can be derived as the actual information.

The flow factor is in particular a measure of the achievable throughput of a fluid (liquid or gas) through the valve. This can also be interpreted a ne effective cross-section.

The differential pressure corresponds in particular to a pressure difference between the gas inlet and the gas outlet. The gas inlet valve can in particular have corresponding pressure sensors for determining the differential pressure.

In one embodiment, the control and processing unit can have a compensation functionality for compensating a position drift from a set position, wherein the compensation functionality is configured in such a way that, when it is executed, the following steps are carried out: Verifying the presence of a position drift, determining or deriving an expression (if a position drift is present), in particular amount and/or direction, of the position drift, and tracking the position of the stop point, in particular varying the position of the stop point in such a way that the set position is provided in the open position.

The position drift can be, in particular, a position deviation of the valve disk in the open position or of the stop point relative to a respective set position for the valve disk or for the stop point.

Checking the presence of the position drift or determining the expression of the position drift can be carried out in particular by means of a position measurement or a flow measurement, by means of a determination of the temperature of the gas inlet valve, or based on a number of opening cycles carried out with the gas inlet valve.

For example, it may be known from experience that the valve exhibits a certain drift after a certain number of opening and closing cycles, e.g. wear-related offset of the valve disk or wear of the seal. Based on this information, a compensating readjustment of the stop point can then be performed continuously or in discrete steps, e.g. for the first time after a certain number of cycles.

According to another example, a drift behavior can be determined in advance or known depending on the thermal state of the valve, i.e. the current temperature of the valve. The adjustment of the stop point can then be carried out accordingly, counteracting the drift.

Furthermore, the principle of the invention can be used, for example, to compensate not only for wear-related drift but also for a narrowing of a flow cross-section due to deposits (deposition), e.g. caused by process gases (especially precursors).

In order to provide a constant gas input into a process volume, a compensation of the flow rate during the gas inlet can also take place by adjusting the stop point. Such compensation can be advantageous due to a pressure drop in the upstream reservoir that occurs in the process.

In one embodiment of the gas inlet valve, the pneumatic drive cylinder may include a further piston, wherein the pistons each delimit respective drive inner volumes. Each of the drive inner volumes can be connected to a respective compressed air channel and the compressed air channels can be arranged in such a way that the pistons can be adjusted in the opening direction by pressurization of the drive inner volumes by means of the compressed air channels and the valve disk can thereby be brought into the open position.

In one embodiment of the gas inlet valve, the sealing surface, the valve disk, and the sealing element may have a circular cross-section, wherein the inner volume is at least partially cylindrical, and wherein the sealing surface is formed by a shoulder in the inner volume.

The cylindrical shape of the inner volume is formed in particular by the gas passage unit as the shell surface and the sealing element as the base surface, wherein gas inlet and gas outlet can gain free access to the inner volume via the shell surface. This means that gas inlet and gas outlet can each pierce the shell surface.

In particular, the disk divides the inner volume in the closed position into a first and a second partial inner volume, with the gas inlet having free access to the first partial volume and the gas outlet having free access to the second partial volume,

In the arrangement provided in connection with a vacuum chamber, the gas outlet has in particular free access to the vacuum process chamber and the gas inlet in particular has free access to a process gas source.

### BRIEF DESCRIPTION OF THE DRAWINGS

Further advantages of the present invention are apparent from the detailed description and drawings.

FIG. 1 shows a sectional view of an embodiment of a gas inlet valve according to the invention;

FIG. 2 shows the gas inlet valve of the invention of FIG. 1 in a sectional view rotated about a vertical axis relative to FIG. 1; and

FIG. 3 shows in detail the inner volume of the gas inlet valve.

### DETAILED DESCRIPTION OF THE DRAWINGS

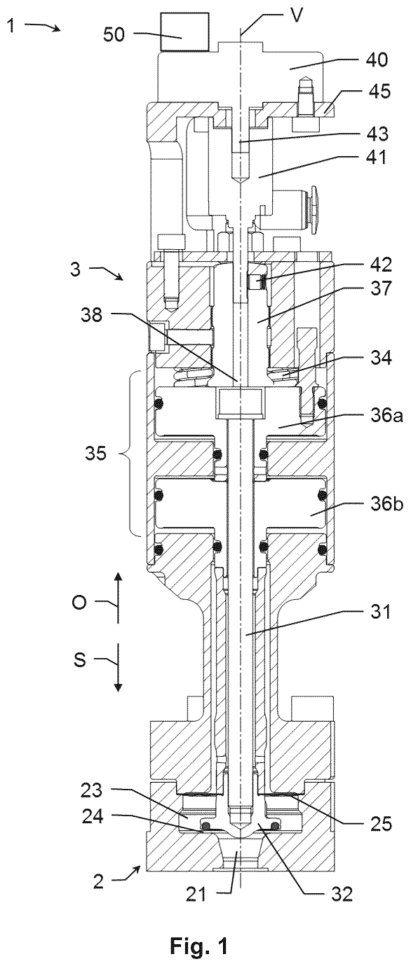

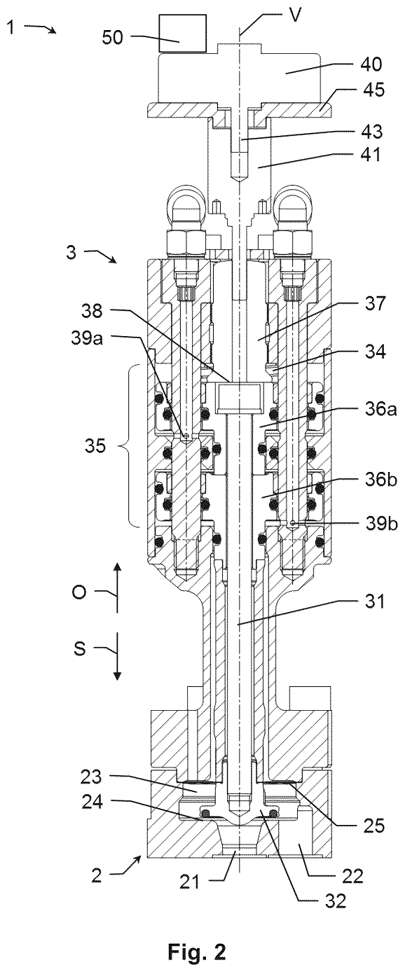

FIGS. 1 and 2 show an exemplary embodiment of a gas inlet valve 1 according to the invention. FIG. 1 shows the valve rotated by 90° about the adjustment axis V relative to the representation in FIG. 2. The gas inlet valve 1 has a gas passage unit 2, which in turn has a gas inlet 21, a gas outlet 22 and an inner volume 23, wherein the inner volume 23 has free access to the gas inlet 21 and to the gas outlet 22 or connects them. The gas passage unit 2 has a sealing surface 24 in the inner volume 23.

The gas inlet valve 1 also has an adjustment device 3 having an adjustment unit 31 and a valve disk 32, wherein the adjustment unit 31 projects into the inner volume 23 and is adjustably mounted in the adjustment device 3 outside the gas passage unit 2. The valve disk 32 is arranged inside the inner volume 23 and can be brought by means of the adjustment device 3 into a closed position, in which the disk 32 rests on the sealing surface 24 and thus prevents gas from passing through. By means of the adjustment device 3, the disk can also be brought into an open position, in which the disk 32 is spaced from the sealing surface 24 and thus allows gas to pass through.

The adjustment device 3 also has a pretensioning or restoring element 34 in the form of a spring. The spring 34 is arranged in a pretensioned manner in the adjustment device 3 in such a way that it exerts a force in the direction of the valve seat and presses the adjustment unit 31 or the valve disk 32 onto the sealing surface 24, i.e. in the closing direction S.

Via the pretensioning in the spring or several springs, the disk 32 is pressed against the sealing surface 24 in a closed position. Here, a sealing ring 33 serves as a gas-tight seal. This sealing ring consists in particular of an elastomer, thermoplastic, metal, etc., can have a shape adapted to the shape of the disk (e.g. an O-ring), or can be vulcanized to the disk.

The sealing ring may be disposed on the disk 32 (as shown here), or it may be disposed on the sealing surface 24 (in other embodiments).

Furthermore, the adjustment device 3 has a pneumatic drive cylinder 35 for exerting an opening force counteracting the pretensioning force and thus providing an opening movement of the valve disk 32. In the embodiment shown, the drive cylinder 35 has two pistons 36a and 36b, wherein the pistons 36a and 36b, or at least one of the pistons 36a, are coupled to the adjustment unit 31 and an opening movement of the adjustment unit 31 can be generated by applying pressure to the drive cylinder 35.

In the embodiment shown, the pretensioning element 3 interacts with the piston 36a and presses it in the closing direction S.

Pressurization of the drive cylinder or pistons 36a and 36b can be provided by means of the two compressed air outlets 39a and 39b connected to (respectively) external pneumatic valves.

The invention also relates to embodiments of the drive cylinder 35 with only one piston or one more than two pistons (not shown), wherein the piston arrangement is provided for opening the valve by means of pressurization.

The gas inlet valve 1 further has a flexible sealing element 25, which in the example shown is designed as a diaphragm, in particular a metal diaphragm. The sealing element is attached to the gas passage unit 2 and to the adjustment unit 31 and thus seals the inner volume 23.

The diaphragm 25, which is designed as a flexible sealing element, provides a flexible seal of the inner volume with respect to the adjustment device 3. For this purpose, the diaphragm 25 is connected on the one hand to the gas passage unit 2 and on the other hand to the adjustment unit, here to the disk 32 or to the rod, The adjustment device 3 has a limiting element 37, which limiting element 37 provides a stop point 38 that limits adjustability of the adjustment unit 31 along the adjustment axis V in the opening direction O. In this case, the limiting element 37 is formed and mounted in such a way that a position of the stop point 38 along the adjustment axis V can be varied by actuating the limiting element 37, The position of the stop point 38 defines a maximum valve opening or valve stroke.

In particular, the stop point 8 is provided by an underside or lower edge of the limiting element 37.

In the context of the invention, an actuation of the limiting element 37 is particularly understood as a displacement, shifting, rotation, etc. of the limiting element 37.

In the embodiment shown, the gas inlet valve 1 is shown in the open position, Here, the piston 36a is in contact with the limiting element 37, in particular with the underside of the limiting element 37, and cannot be moved further in the opening direction O as a result. Due to the coupling or connection of the adjustment unit 31 with the piston 36a, the adjustment of the adjustment unit 31 or the valve disk 32 is thus also limited accordingly.

The gas inlet valve 1 further comprises a motor 40. The motor 40 can be designed as a drive 40, e.g. as an electric motor, servomotor or stepper motor. The actuation of the motor 40 may be controlled, in particular, by means of a control and processing unit 50. For example, a certain number of motor revolutions and their direction can be executed in a controlled manner. The motor 40 is not to be understood as the drive or the drive cylinder for executing the valve movement (opening and closing).

The motor 40 is coupled to the limiting element 37. In the embodiment shown, a coupling element 41 is provided, which is connected to the limiting element 37 on its underside by means of a pin. In the example shown, the coupling element 41 is designed as a gear. Here, the pin is located in a corresponding recess of the limiting element 37 and is locked by means of a screw connection. Here, the pin is clamped in the recess by a screw 42.

The coupling element 41 is coupled to the motor 40 at its upper side, in particular connected to a motor shaft 43 of the motor 40. The motor shaft 43 engages in a recess of the coupling element 41. Here, the motor shaft 43 may have an external thread, and the recess of the coupling element 41 may have an internal thread corresponding to and cooperating with the external thread. The coupling element 41 is, at least to a large extent, arranged in a rotationally fixed manner relative to the motor 40. The motor shaft 43 may be at least partially formed as a threaded rod or spindle.

Due to the coupled arrangement of the motor 40, the coupling element 41 and the limiting element 37, the limiting element can be displaced along the displacement axis V by means of an actuation of the motor 40, i.e. a rotation of the motor shaft 43. Thus, a position of the stop point 38 can be changed along the adjustment axis V.

In an alternative embodiment (not shown here), the coupling element 41 and the limiting element 37 may be formed integrally, or the limiting element 37 may be coupled directly to the motor 40. Alternatively, the coupling element 41 and the limiting element 37 may be connected in another manner known to those skilled in the art, e.g. glued, welded or soldered.

The gas inlet valve 1 also has a retaining element 45 by which the motor 40 is retained. For example, the motor 40 may be bolted to the retaining element 45. In an alternative embodiment (not shown), the motor 40 may be integrated into the adjustment device 30 or a valve housing.

Connections can be provided for the gas inlet 21 and for the gas outlet 22. The line to the gas source and the line to the vacuum process chamber can be connected via these.

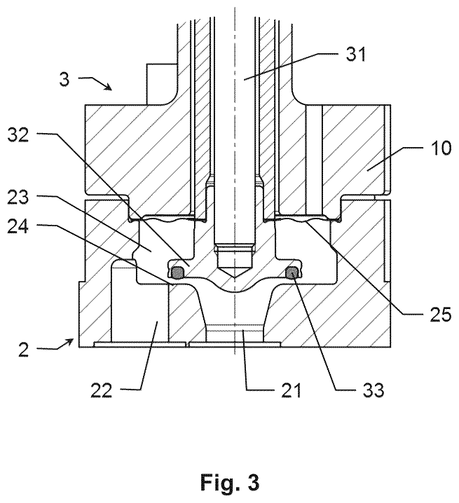

FIG. 3 shows the gas passage unit 2 in detail, in particular the disk 32 adjustable therein and the flexible sealing element 25, which in the embodiment shown is clamped between the gas passage unit 2 and the adjustment device 3, or between the gas passage unit 2 and a counter component 10. This clamping can be provided, for example, by a screw connection.

The fit of the flexible sealing element 25 to the adjustment unit 31 can also be achieved by clamping. The person skilled in the art is familiar with a wealth of such design options for connecting the sealing element to the adjustment unit so that the disk remains adjustable in the inner volume 23.

The control and processing unit 50 has an adjustment functionality for adjusting the position of the stop point 38 by a controlled actuation of the motor 40. For this purpose, a reference information, e.g. a set pressure, a set temperature, a set flow rate, etc., is processed and compared with a corresponding actual information. Based on the result of the comparison (adjustment information), e.g. a deviation of an actual value from a setpoint value derived therefrom, the limiting element 37 can be adjusted by a corresponding distance and the position of the stop point 38 can thus be readjusted.

For example, a flow rate through the valve 1 in the open position can be measured and, if there is any deviation from a set flow rate, the maximum valve opening cross section can be readjusted. As an alternative to direct measurement of the flow rate, a density and/or a temperature of the fluid or a pressure or differential pressure can be determined and a fluid flow rate for the fluid can be concluded from the respective measured variable, in particular the actual fluid flow rate can be calculated on the basis of this variable.

The control and processing unit 50 may further or alternatively comprise a compensation functionality for compensating a position drift from a set position. In this case, it can first be checked whether a position drift is present, for example by means of an external position determination for the disk 32 or the flow measurement in an open position, e.g. when the adjustment unit 31 or the piston 36 strikes the limiting element (37).

If a position drift is detected, a characteristic of this drift, in particular an amount and/or a direction, can be determined. On the basis of the determined characteristic, the position of the stop point can then be readjusted, in particular varied in such a way that the desired nominal position is provided in the open position.

In particular, the control and processing unit 50 is also connected to the pneumatic valves and is able to control the opening and closing of the gas inlet valve.

A further advantage of the gas inlet valve according to the invention is that in a first partial volume, to which the gas inlet 21 has free access, a gas supply can accumulate, so to speak, which, when the gas inlet valve 1 is opened, can be passed on fluidically advantageously and abruptly to a second partial volume connected to the gas outlet. Measured against these fluidic advantages, the gas inlet valve according to the invention also has a very small size.

The figures always show a disk 32 having upper and lower axial parts (hollow shaft sections). In other embodiments, the disk 32 may be merely a disk, in which case the upper and lower portions of the disk 32 may be replaced by simple hollow shafts that are sealed axially with respect to the disk. Furthermore, the figures always show a disk 32 which is opened in the gas flow direction, i.e. which is adjusted from top to bottom according to the figures. In other exemplary embodiments, however, the components involved can also be designed and arranged in such a way that the disk is pressed onto the sealing surface from above for the closed position, and is moved upwards for an open position.

While the invention has been explained in terms of its preferred embodiment(s), many other changes and variations can be made without going beyond the scope of the present invention, Therefore, it is intended that the appended claims cover changes and variations included in the actual scope of the invention.

1. A gas inlet valve for controlled inlet of a fluid into a vacuum process chamber, wherein the gas inlet valve comprises:
a gas passage unit having a gas inlet, a gas outlet, and an inner volume connecting the gas inlet and the gas outlet, wherein the gas passage unit has a sealing surface in the inner volume,
an adjustment device having an adjustment unit, wherein the adjustment unit projects into the inner volume and is adjustably mounted outside the gas passage unit in the adjustment device along an adjustment axis, wherein the adjustment unit has a valve disk which is arranged inside the inner volume, wherein the valve disk can be brought by means of the adjustment device in the closing direction into a closed position, in which the valve disk rests on the sealing surface and gas flow is thus prevented, and wherein the valve disk can be brought by means of the adjustment device in the opening direction into an open position, in which the valve disk is spaced from the sealing surface and a gas flow is provided, and
a flexible sealing element which is attached to the gas passage unit and to the adjustment unit and seals the adjustment unit from the inner volume,
wherein:
the adjustment device has a pneumatic drive cylinder having at least one piston, wherein the piston is coupled to the adjustment unit, and an opening force can be generated in the opening direction by pressurization of the drive cylinder.
wherein:
the adjustment device has a limiting element, which limiting element provides a stop point which limits adjustability of the adjustment unit along the adjustment axis in the opening direction, and
the limiting element is shaped and mounted in such a way that a position of the stop point along the installation axis can be varied by means of actuation of the limiting element, wherein the position of the stop point defines a maximum valve opening.

2. The gas inlet valve according to claim 1, wherein
the adjustment device has a pretensioning element arranged and interacting with the adjustment unit in such a way that a pretensioning force pressing the valve disk in the closing direction is provided, and
the pressurization of the drive cylinder can generate an opening force in the opening direction that counteracts the pretensioning force.

3. The gas inlet valve according to claim 1, wherein the gas inlet valve has a controllable drive and the drive is connected or coupled to the limiting element in such a way that the position of the stop point can be varied by means of the drive.

4. The gas inlet valve according to claim 3, wherein the drive is designed as an electric motor, in particular a stepper motor, as a piezo element or as an actuator based on the magnetic bearing principle.

5. The gas inlet valve according to claim 1, wherein:
the gas inlet valve comprises a control and processing unit arranged to control the actuator.

6. The gas inlet valve according to claim 5, wherein the control and processing unit comprises an adjustment functionality for adjusting the position of the stop point, wherein the adjustment functionality is configured such that upon execution thereof the following steps are carried out:
processing reference information,
processing actual information,
comparing the reference information with the actual information,
deriving adjustment information based on the comparison, and
adjusting the position of the stop point using the adjustment information, in particular automatic adjustment.

7. The gas inlet valve according to claim 6, wherein the actual information comprises: information about a fluid property, in particular composition, nature or type of the fluid, and the reference information provides an assignment of fluid properties to respective positions of the stop point.

8. The gas inlet valve according to claim 6, wherein the reference information comprises information about a desired pressure of the fluid and the actual information indicates a current fluid pressure, in particular wherein the gas inlet valve comprises at least one pressure sensor for determining the fluid pressure.

9. The gas inlet valve according to claim 6, wherein:
the reference information comprises information about a set temperature of the fluid and the actual information indicates a current fluid temperature, in particular wherein the gas inlet valve comprises a temperature sensor for determining the fluid temperature.

10. The gas inlet valve according to claim 6, wherein:
the reference information comprises information about a set flow factor for the fluid and the actual information indicates a current fluid flow factor, in particular wherein the gas inlet valve comprises a flow measuring unit for determining the fluid flow factor.

11. The gas inlet valve according to claim 6, wherein:
the reference information comprises information about a set flow factor and the actual information indicates a density and/or temperature of the fluid or a differential pressure, in particular wherein by means of the density and/or temperature of the fluid and/or by means of the differential pressure a fluid flow factor for the fluid can be derived as the actual information.

12. The gas inlet valve according to claim 5, wherein:
the control and processing unit comprises a compensation functionality for compensating a position drift from a desired position, wherein the compensation functionality is configured such that upon execution thereof the following steps are carried out:
verifying the presence of a position drift,
determining or deriving an expression (if a position drift is present), in particular amount and/or direction, of the position drift, and
tracking the position of the stop point, in particular varying the position of the stop point in such a way that the set position is provided in the open position.

13. The gas inlet valve according to claim 12, wherein the position drift is a positional deviation of the valve disk in the open position or of the stop point relative to a respective set position for the valve disk or for the stop point.

14. The gas inlet valve according to claim 12, wherein checking the presence of the position drift or determining the expression of the position drift is carried out:
by means of a position measurement or a flow measurement,
by means of a determination of the temperature of the gas inlet valve, or
based on the number of opening cycles carried out with the gas inlet valve.

15. The gas inlet valve according to claim 1, wherein:
the pneumatic drive cylinder has a further piston and the pistons each delimit respective drive inner volumes,
each of the drive inner volumes is connected to a respective compressed air channel and the compressed air channels are arranged in such a way that the pistons can be adjusted in the opening direction by pressurization of the drive inner volumes by means of the compressed air channels and the valve disk can thereby be brought into the open position.

16. The gas inlet valve according to claim 1, wherein the sealing surface, the valve disk and the sealing element have a circular cross-section, wherein the inner volume is cylindrical at least in sections, and wherein the sealing surface is formed by a shoulder in the inner volume.
